(19) United States
(12) Patent Application Publication
(10) Pub. No.: US 2026/0271186 A1
(43) Pub. Date: Sep. 10, 2026

(54) CIRCUIT BOARD WITH HYBRID WIRING STRUCTURE

(71) Applicant: Primax Electronics Ltd., Taipei (TW)

(72) Inventors: Yi-Chao Huang, Taipei (TW); Yu-Zeng Yang, Taipei (TW)

(21) Appl. No.: 19/182,284

(22) Filed: Apr. 17, 2025

(30) Foreign Application Priority Data
Mar. 6, 2025 (TW) 114108342

(51) Int. Cl. H05K 1/09; H05K 1/03; H05K 1/16

(52) U.S. Cl. CPC H05K 1/092; H05K 1/0306; H05K 1/167; H05K 2201/05; H05K 2201/0776; H05K 2201/09227; H05K 2201/10113

(57) ABSTRACT

A circuit board with a hybrid wiring structure is provided. The circuit board includes a substrate, a low-impedance wiring set and a printed wiring set. The low-impedance wiring set includes at least one first low-impedance conductive trace and a second low-impedance conductive trace. The first low-impedance conductive trace is formed on a first surface of the substrate. The second low-impedance conductive trace is formed in the substrate. The printed wiring set includes a printed conductive trace. The printed conductive trace is formed on the first surface of the substrate. The printed conductive trace is electrically connected with two first low-impedance conductive traces. The resistance value of the printed wiring set is higher than the resistance value of the low-impedance wiring set.

### FIELD OF THE INVENTION

The present invention relates to a substrate structure, and more particularly to a circuit board with a wiring design.

### BACKGROUND OF THE INVENTION

Circuit boards can be used to install various electronic components. Consequently, circuit boards are widely used in various types of electronic products. For example, flexible circuit boards (FCBs) are classified into flexible printed circuits (FPCs), flexible flat cables (FFCs), flexible die-cutting circuits (FDCs) and flexible printed ink circuits (FPICs).

The flexible printed circuit is a single-layer or multi-layer circuit board that is made of flexible material and has a three-dimensional wiring structure. This technology have some advantages. For example, the flexible printed circuit has high flexibility to adapt to the wiring needs of small spaces, has high reliability to be suitable for high frequency and high temperature environments, and has excellent electrical performance to support high current applications. However, the flexible printed circuit has some drawbacks. For example, the manufacturing cost is high, the manufacturing process is difficult, and the processing and maintenance difficulty is high. Furthermore, during the manufacturing process, the chemicals used in the etching procedure are also likely to cause environmental pollution.

The flexible flat cable is a flat circuit that is formed by embedding parallel rolled copper wires into a plastic substrate. In addition, the flexible flat cable is mainly used for two-dimensional planar wiring applications. This technology have some advantages. For example, the manufacturing cost is low, the manufacturing process is simple, and the flexible flat cable is easy to use and suitably used for short-distance circuit connection. Furthermore, the flexible flat cable has stable electrical properties and can meet the ordinary current and signal transmission requirements. However, the flexible flat cable is only suitable for the simple two-dimensional electrical connection and is unable to be applied to the multi-layer structure design. In other words, the applications of the flexible flat cable are limited.

The flexible die-cutting circuit is formed on a flexible material through a precision die-cutting technology. The shape and size of the flexible die-cutting circuit can be customized according to the practical requirements. This technology have some advantages. For example, the flexible die-cutting circuit can be customized to meet specified application requirements. Since the flexible die-cutting circuit can be pre-cut into specified shapes, the flexible die-cutting circuit can be easily installed in corresponding electronic products. Furthermore, the flexible die-cutting circuit is lightweight and thin to meet the needs of today’s consumer electronic products for thinness and lightness. However, the production of the flexible die-cutting circuit relies on high-precision die-cutting equipment, and its mold cost is relatively high. If the design of the flexible die-cutting circuit is changed, the manufacturing cost will be greatly increased. Furthermore, due to the restrictions on its circuit design, the flexible die-cutting circuit is usually used for local connection lines and rarely used as a complete circuit board.

The flexible printed ink circuit is formed by printing conductive ink on a flexible substrate as electrical connection wire. This technology has some advantages such as simple manufacturing process, low manufacturing cost and fast production speed. In addition, the flexible printed ink circuit is suitable for large-scale production and rapid iterative development. Since the manufacturing process is simple, few pollution sources are generated during its manufacturing process. Furthermore, the overall weight is relatively light. Consequently, even if the electronic product is replaced, the waste is not likely to cause environmental pollution. However, the electrical performance of the flexible printed ink circuit is not as good as that of the circuit boards using metal wires. Since the resistance value of conductive ink is relatively high, it is easy to produce electrical instability. Due to its poor durability, it is easily affected by environmental factors such as temperature, humidity or moisture. Since the precision and density of the conductive ink are limited by the printing process, it is difficult for the conductive ink to realize complex circuit designs.

In order to overcome the drawbacks of the conventional technologies, it is important to provide a circuit board with reduced process complexity and reduced chemical pollutant generation while having both electrical stability and wiring flexibility.

### SUMMARY OF THE INVENTION

The present invention provides a circuit board with a hybrid wiring structure. The manufacturing process of the circuit board is simple, and the generation of chemical pollutants can be effectively reduced. Furthermore, the conductive stability and the wiring flexibility are enhanced.

In accordance with an aspect of the present invention, a circuit board with a hybrid wiring structure is provided. The circuit board includes a substrate, at least one low-impedance wiring set and at least one printed wiring set. The substrate has a first surface and a second surface, which are opposed to each other. The at least one low-impedance wiring set has a first resistance value. The at least one low-impedance wiring set includes at least one first low-impedance conductive trace. The at least one first low-impedance conductive trace is formed on the first surface of the substrate. The at least one printed wiring set has a second resistance value. The at least one printed wiring set includes at least one printed conductive trace. The at least one printed conductive trace is formed on the first surface of the substrate. The at least one printed conductive trace is electrically connected with the at least one first low-impedance conductive trace. The second resistance value is higher than the first resistance value.

In an embodiment, the at least one printed wiring set is formed by printing conductive ink on the first surface of the substrate. The conductive ink is made of silver paste, copper paste, copper-silver mixed paste or carbon material.

In an embodiment, the circuit board further includes a connector, and at least one first low-impedance conductive trace include a plurality of first low-impedance conductive traces. Moreover, two terminals of the connector are electrically connected with two of the plurality of first low-impedance conductive traces, respectively.

In an embodiment, the connector is a sold pad, a via hole, a connecting copper foil or a connecting terminal.

In an embodiment, the circuit board further includes at least one illumination module, and the at least one illumination module is installed on the first surface of the substrate. The at least one printed wiring set is electrically connected with the at least one illumination module in series or in parallel.

In an embodiment, one of the at least one printed conductive trace has a current limiting resistor.

In an embodiment, the substrate is made of glass fiber epoxy resin, paper phenolic resin, glass fiber composite epoxy resin, ceramic material, polyimide or polyethylene terephthalate.

In an embodiment, a ratio of a resistivity of the low-impedance wiring set to a resistivity of the printed wiring set is less than or equal to 0.3.

In an embodiment, the circuit board further includes at least one electronic component, and the at least one electronic component is installed on the first surface of the substrate. The at least one printed wiring set is electrically connected with the at least one electronic component. The at least one electronic component includes a resistor, a capacitor, an inductor, a transistor, an integrated circuit, an optocoupler, a connector or a relay.

In an embodiment, the circuit board further includes at least one second low-impedance conductive trace. The at least one second low-impedance conductive trace is formed in the substrate and extended toward the second surface of the substrate. The at least one second low-impedance conductive trace is electrically connected with the at least one first low-impedance conductive trace.

In an embodiment, the circuit board further includes at least one additional conductive trace. The at least one additional conductive trace is formed in the substrate and extended toward the second surface of the substrate. The at least one additional conductive trace is electrically connected with the at least one first low-impedance conductive trace. The additional conductive trace has a third resistance value. The third resistance value is higher or lower than the first resistance value.

From the above descriptions, the present invention provides a circuit board with a hybrid wiring structure. The use of the low-impedance wiring set can provide good conductivity and satisfied conductive stability. Due to the printing characteristics of the printed wiring sets, the overall wiring flexibility can be further improved. Consequently, the circuit board can be suitably applied to various electronic components. For example, the electronic components include illumination modules or light-emitting units with different light-emitting surfaces, resistors, capacitors, inductors, transistors, integrated circuits, optocouplers, connectors or relays. In addition, the circuit board with the hybrid wiring structure can be used as a bridge circuit between low-impedance wiring sets. In addition, the manufacturing process is simple, and the generation of chemical pollutants can be effectively reduced.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1A is a schematic cross-sectional view illustrating a circuit board with a hybrid wiring structure according to a first embodiment of the present invention;

FIG. 1B is a schematic top view illustrating the circuit board with the hybrid wiring structure according to the first embodiment of the present invention;

FIG. 2 is a schematic top view illustrating a circuit board with a hybrid wiring structure according to a second embodiment of the present invention;

FIG. 3 is a schematic top view illustrating a circuit board with a hybrid wiring structure according to a third embodiment of the present invention; and

FIG. 4 is a schematic top view illustrating a circuit board with a hybrid wiring structure according to a fourth embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

For illustration, the Y-axis direction in the figures is defined as a first direction Y, and the X-axis direction in the figures is defined as a second direction X. The first direction Y and the second direction X are perpendicular to each other.

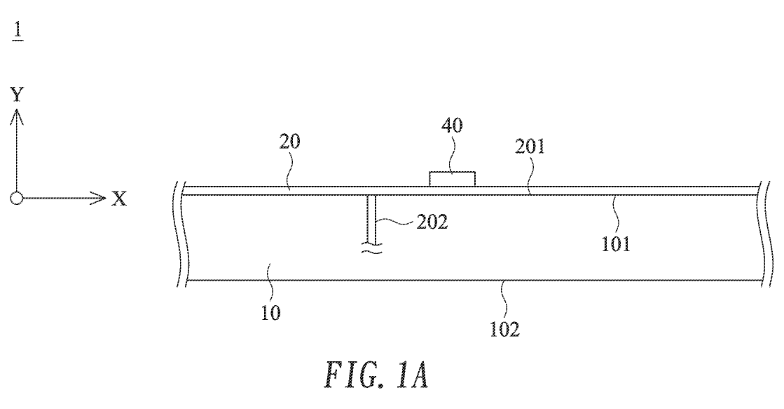

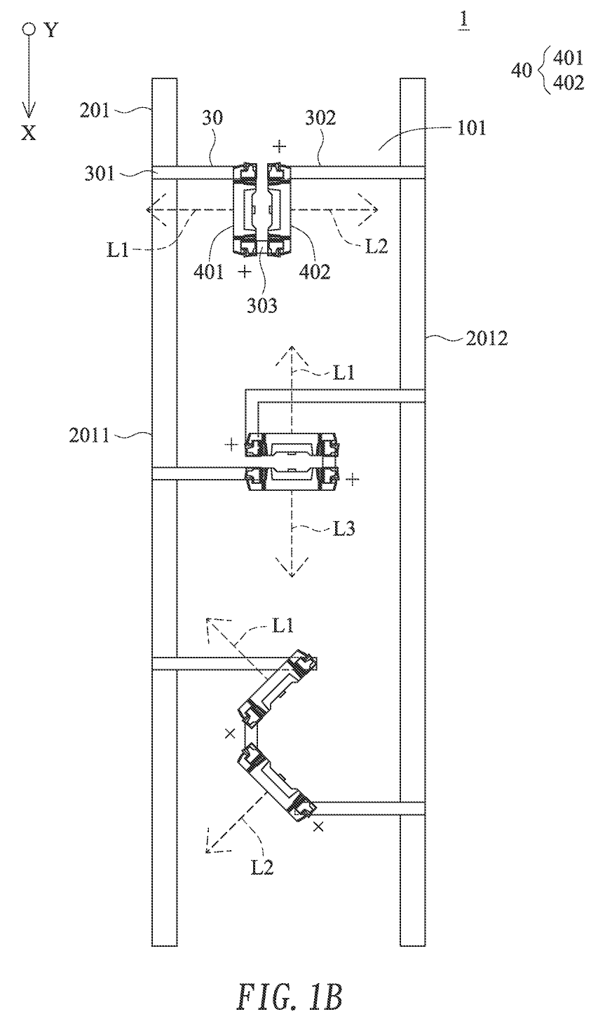

Please refer to FIG. 1A and FIG. 1B. FIG. 1A is a schematic cross-sectional view illustrating a circuit board with a hybrid wiring structure according to a first embodiment of the present invention. FIG. 1B is a schematic top view illustrating the circuit board with the hybrid wiring structure according to the first embodiment of the present invention.

In this embodiment, the circuit board 1 with the hybrid wiring structure includes a substrate 10, a low-impedance wiring set 20, a printed wiring set 30 and an illumination module 40.

The substrate 10 has a first surface 101 and a second surface 102, which are opposed to each other. The substrate 10 is made of glass fiber epoxy resin (FR-4), paper phenolic resin (FR-1), glass fiber composite epoxy resin (CEM-3), ceramic material (Ceramic PCB), polyimide (PI) or polyethylene terephthalate (PET).

In an embodiment, the low-impedance wiring set 20 is formed in the substrate 10 through an FPC flexible circuit board process, so that a three-dimensional circuit design of the low-impedance wiring set 20 is produced. The substrate 10 has a single-layer or multi-layer structure. Subsequently, copper wires are embedded in the surface of the substrate 10 through a heat pressing process, so that a two-dimensional circuit design of the low-impedance wiring set 20 is produced. Due to the two-dimensional and three-dimensional circuit layouts, the low-impedance wiring set 20 includes at least one first low-impedance conductive trace 201 and at least one second low-impedance conductive trace 202. The first low-impedance conductive trace 201 is formed on the first surface 101 of the substrate 10. The second low-impedance conductive trace 202 is formed in the substrate 10 and extended in the direction toward the second surface 102 of the substrate 10. The end of the second low-impedance conductive trace 202 close to the first surface 101 of the substrate 10 is electrically connected with the first low-impedance conductive trace 201. In this embodiment, the second low-impedance conductive trace 202 is extended along the first direction Y. The low-impedance wiring set 20 has a first resistance value. For example, the first resistance value is about 0.1 ohm (Ω). Of course, the resistivity (ρ) of the low-impedance wiring set 20 can be adjusted according to the width, thickness and length of the conductive trace.

In some possible embodiments, an additional conductive trace (not shown) is formed in the substrate 10. The additional conductive trace is also extended along the first direction Y, but the additional conductive trace does not belong to the low-impedance wiring set 20. The additional conductive trace is electrically connected with the at least one first low-impedance conductive trace. The additional conductive trace has a third resistance value. The third resistance value is higher or lower than the first resistance value. The printed wiring set 30 is formed on the first surface 101 of the substrate 10. In addition, the printed wiring set 30 includes one or more printed conductive traces. In this embodiment, the printed wiring set 30 includes printed conductive traces 301, 302 and 303.

The illumination module 40 is installed on the first surface 101 of the substrate 10. In an embodiment, the illumination module 40 includes at least one first light-emitting unit 401 and at least one second light-emitting unit 402.

In this embodiment, the at least one first low-impedance conductive trace 201 includes a first low-impedance conductive trace 2011 and a first low-impedance conductive trace 2012. A first terminal of the printed conductive trace 301 is electrically connected with the first low-impedance conductive trace 2011. A second terminal of the printed conductive trace 301 is electrically connected with the negative terminal of the first light-emitting unit 401. A first terminal of the printed conductive trace 302 is electrically connected with the first low-impedance conductive trace 2012. A second terminal of the printed conductive trace 302 is electrically connected with the positive terminal of the second light-emitting unit 402. A first terminal of the printed conductive trace 303 is electrically connected with the positive terminal of the first light-emitting unit 401. A second terminal of the printed conductive trace 303 is electrically connected with the negative terminal of the second light-emitting unit 402. Consequently, the printed wiring set 30 is electrically connected with the illumination module 40 in series.

The printed wiring set 30 includes a plurality of printed conductive traces by printing conductive ink on the first surface 101 of the substrate 10. For example, the conductive ink is made of silver paste, copper paste, copper-silver mixed paste or carbon material. The carbon material is graphite, graphene, carbon black, carbon fiber or carbon nanotube. In this embodiment, the printed wiring set 30 has a second resistance value. For example, the second resistance value is about 15 ohms (Ω). Of course, the resistivity (ρ) of the printed wiring set 30 can be adjusted according to the width, thickness and length of the conductive trace. After the width, thickness and length of the traces are properly adjusted, at room temperature, the ratio of the resistivity (ρ1) of the low-impedance wiring set 20 to the resistivity (ρ2) of the printed wiring set 30 is less than or equal to 0.3. That is, (ρ1/ρ2) ≤ 0.3.

The low-impedance wiring set 20 has lower resistance value and resistivity. The printed wiring set 30 formed by printing conductive ink has higher resistance value and resistivity. Consequently, when an electronic device provides a rated voltage to the circuit board 1 with the hybrid wiring structure, the current can flow through the circuit board 1 stably and quickly because the low-impedance wiring set 20 has the lower resistance value and resistivity. When the current flows into the printed wiring set 30, a smaller current flows through the printed wiring set 30 to drive the illumination module 40 because of its higher resistance value and resistivity. Due to the flexible design of the printed conductive trace of the printed wiring set 30, the first light-emitting unit 401 and the second light-emitting unit 402 of the illumination module 40 can emit light beams L1 and L2 in different directions according to the design of their orientations. As shown in FIG. 1B, the illumination module 40 includes three first light-emitting units 401 and three second light-emitting units 402, which are arranged sequentially from the upper region to the lower region. The first light-emitting unit 401 and the second light-emitting unit 402 in the upper region respectively emit the light beams L1 and L2 in the left direction and the right direction. The first light-emitting unit 401 and the second light-emitting unit 402 in the middle region respectively emit the light beams L1 and L2 in the upward direction and the downward direction. The first light-emitting unit 401 and the second light-emitting unit 402 in the lower region respectively emit the light beams L1 and L2 in the upper left direction and the lower left direction.

In the above implementation example, the illumination module 40 is an electronic component installed on the substrate 10. It is noted that the example of the electronic component is not restricted. In the practical applications, the printed wiring set 30 is formed by printing various printed traces according to the installations or requirements of different types of electronic devices.

In the above implementation example, the electronic component is installed on the first surface 101 of the substrate 10. It is noted that the installation of the electronic component is not restricted. For example, in another embodiment, the electronic component is installed on the second surface 102 of the substrate 10. In addition, the electronic component on the second surface 102 of the substrate 10 can be electrically connected with or controlled by the printed wiring set (not shown) on the second surface 102 of the substrate 10 and the second low-impedance conductive trace 202.

In the above implementation example, two first low-impedance conductive traces 2011 and 2012 are formed on the first surface 101 of the substrate 10. It is noted that numerous modifications may be made while retaining the teachings of the present invention. For example, in another embodiment, only a single first low-impedance conductive trace is formed on the first surface 101 of the substrate 10. In addition, various signal and current conduction paths are defined by the printed wiring set 30.

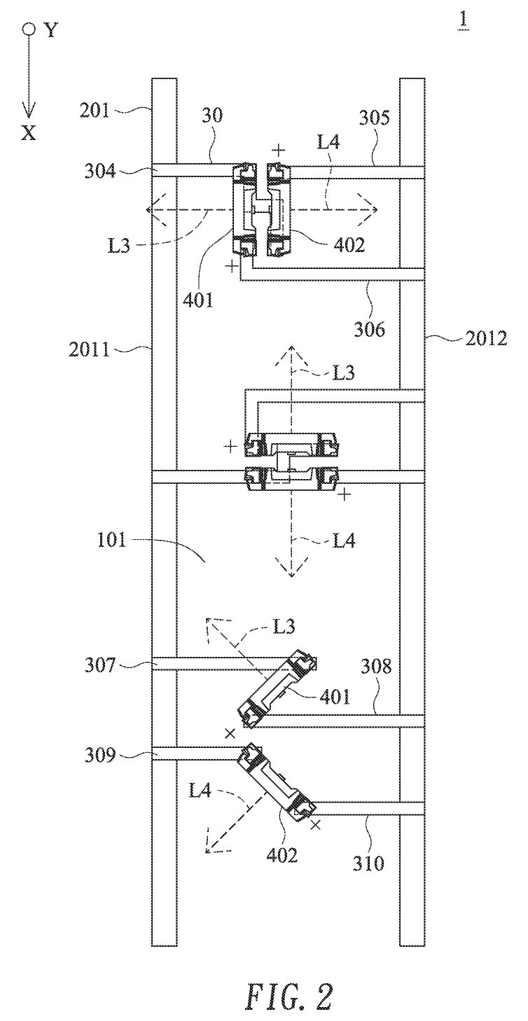

FIG. 2 is a schematic top view illustrating a circuit board with a hybrid wiring structure according to a second embodiment of the present invention. The materials and the functions of the substrate 10, the low-impedance wiring set 20, the printed wiring set 30 and the illumination module 40 in the circuit board of this embodiment are substantially similar to those of the circuit board of the first embodiment shown in FIG. 1B, and not redundantly described herein. However, the connections between the conductive traces of the printed wiring set 30 and the corresponding components in this embodiment are distinguished from the first embodiment.

In this embodiment, the printed wiring set 30 includes printed conductive traces 304, 305 and 306. A first terminal of the printed conductive trace 304 is electrically connected with the first low-impedance conductive trace 2011. A second terminal of the printed conductive trace 304 is electrically connected with the negative terminal of the first light-emitting unit 401 and the negative terminal of the second light-emitting unit 402. A first terminal of the printed conductive trace 305 is electrically connected with the first low-impedance conductive trace 2012. A second terminal of the printed conductive trace 305 is electrically connected with the positive terminal of the second light-emitting unit 402. A first terminal of the printed conductive trace 306 is electrically connected with the first low-impedance conductive trace 2012. A second terminal of the printed conductive trace 306 is electrically connected with the positive terminal of the first light-emitting unit 401. In other words, the printed wiring set 30 is electrically connected with the illumination module 40 in parallel.

When an electronic device provides a rated voltage to the circuit board 1 with the hybrid wiring structure, a current is provided to the illumination module 40 through the low-impedance wiring set 20 and the printed wiring set 30. Consequently, the first light-emitting unit 401 and the second light-emitting unit 402 of the illumination module 40 can emit light beams L3 and L4 in different directions according to the design of their orientations. For example, the first light-emitting unit 401 and the second light-emitting unit 402 respectively emit the light beams L3 and L4 in the left direction and the right direction, or the first light-emitting unit 401 and the second light-emitting unit 402 respectively emit the light beams L3 and L3 in the upward direction and the downward direction. Due to the flexibility of the printing process of the printed wiring set 30, the circuit board 1 with the illumination module 40 can be applied to various types of electronic devices, e.g., the backlight module of a keyboard or a lighting device.

The example of the parallel connection between the printed wiring set 30 and the illumination module 40 is not restricted. Please refer to FIG. 2 again. In an embodiment, the printed wiring set 30 further includes printed conductive traces 307, 308, 309 and 310. A first terminal of the printed conductive trace 307 is electrically connected with the first low-impedance conductive trace 2011. A second terminal of the printed conductive trace 307 is electrically connected with the negative terminal of the first light-emitting unit 401. A first terminal of the printed conductive trace 308 is electrically connected with the first low-impedance conductive trace 2012. A second terminal of the printed conductive trace 308 is electrically connected with the positive terminal of the first light-emitting unit 401. A first terminal of the printed conductive trace 309 is electrically connected with the first low-impedance conductive trace 2011. A second terminal of the printed conductive trace 309 is electrically connected with the negative terminal of the second light-emitting unit 402. A first terminal of the printed conductive trace 310 is electrically connected with the first low-impedance conductive trace 2012. A second terminal of the printed conductive trace 310 is electrically connected with the positive terminal of the second light-emitting unit 402. In other words, the printed wiring set 30 is electrically connected with the illumination module 40 in parallel.

When an electronic device provides a rated voltage to the circuit board 1 with the hybrid wiring structure, a current is provided to the illumination module 40 through the low-impedance wiring set 20 and the printed wiring set 30. Consequently, the first light-emitting unit 401 and the second light-emitting unit 402 of the illumination module 40 can emit light beams L3 and L4 in different directions according to the design of their orientations. The first light-emitting unit 401 and the second light-emitting unit 402 respectively emit the light beams L3 and L4 in the upper left direction and the lower left direction.

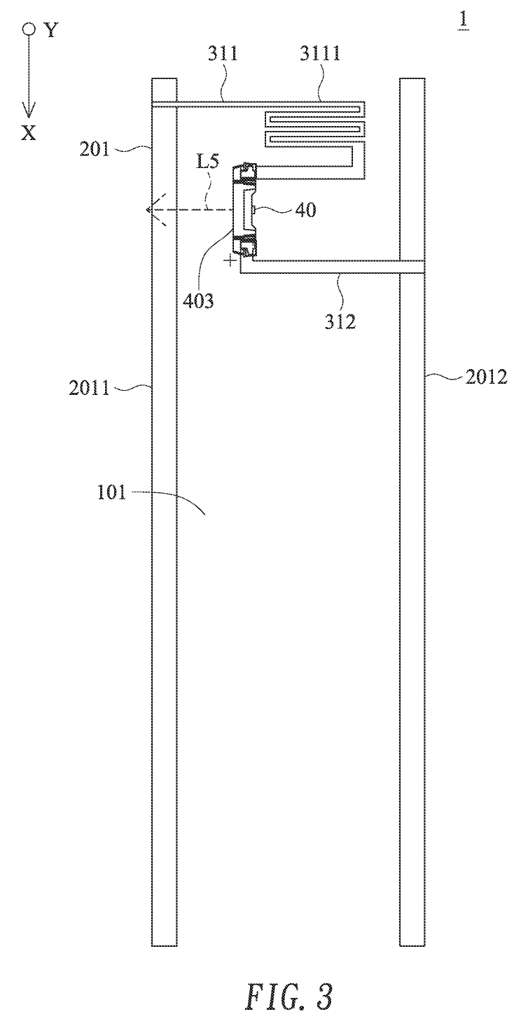

FIG. 3 is a schematic top view illustrating a circuit board with a hybrid wiring structure according to a third embodiment of the present invention. The materials and the functions of the substrate 10, the low-impedance wiring set 20, the printed wiring set 30 and the illumination module 40 in the circuit board of this embodiment are substantially similar to those of the circuit board of the first embodiment shown in FIG. 1B, and not redundantly described herein. However, the constituents of the illumination module 40 in this embodiment are distinguished from the first embodiment. In this embodiment, the illumination module 40 includes a single third light-emitting unit 403. The printed wiring set 30 includes printed conductive traces 311 and 312. A first terminal of the printed conductive trace 311 is electrically connected with the first low-impedance conductive trace 2011. A second terminal of the printed conductive trace 311 is electrically connected with the negative terminal of the third light-emitting unit 403. A first terminal of the printed conductive trace 312 is electrically connected with the first low-impedance conductive trace 2012. A second terminal of the printed conductive trace 312 is electrically connected with the positive terminal of the third light-emitting unit 403. In other words, the printed wiring set 30 is electrically connected with the illumination module 40 in series. In order to reduce the magnitude of the current flowing through the printed wiring set 30, the printed conductive trace 311 is equipped with consecutive bent trace structure through a printing process. The consecutive bent trace structure is formed as a current limiting resistor 3111 for reducing the magnitude of the current flowing through the printed wiring set 30.

When an electronic device provides a rated voltage to the circuit board 1 with the hybrid wiring structure, a current is provided to the illumination module 40 through the low-impedance wiring set 20 and the printed wiring set 30. Consequently, the third light-emitting unit 403 of the illumination module 40 emits light beam L5 in a specified direction according to the design of its orientation.

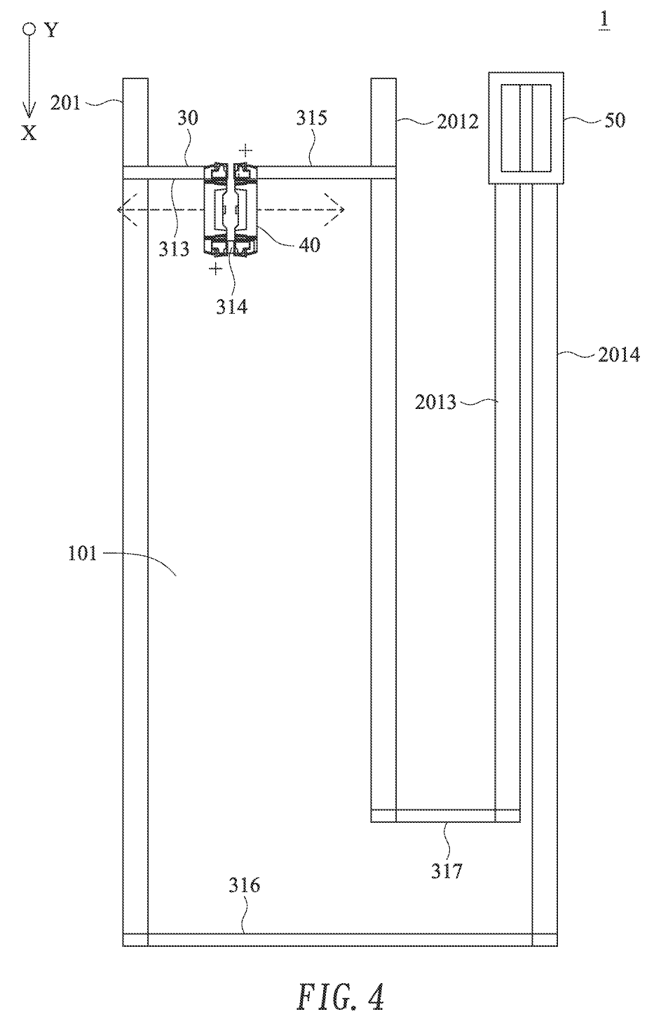

FIG. 4 is a schematic top view illustrating a circuit board with a hybrid wiring structure according to a fourth embodiment of the present invention. The materials and the functions of the substrate 10, the low-impedance wiring set 20, the printed wiring set 30 and the illumination module 40 in the circuit board of this embodiment are substantially similar to those of the circuit board of the first embodiment shown in FIG. 1B, and not redundantly described herein. However, the number of printed conductive traces and the number of first low-impedance conductive traces in the circuit board of this embodiment are distinguished. In this embodiment, the printed wiring set 30 includes printed conductive traces 313, 314, 315, 316 and 317, and the low-impedance wiring set 20 includes first low-impedance conductive traces 2011, 2012, 2013 and 2014. In this embodiment, the circuit board 1 further includes a connector 50. The printed conductive traces 313, 314 and 315 are electrically connected with the first low-impedance conductive traces 2011 and 2012 and electrically connected with the illumination module 40 in series.

The two terminals of the connector 50 are electrically connected with a first terminal of the first low-impedance conductive trace 2013 and a first terminal of the first low-impedance conductive trace 2014, respectively. The printed conductive trace 316 is electrically connected with a terminal of the first low-impedance conductive trace 2011 and a second terminal of the first low-impedance conductive trace 2014 (i.e., the terminal of the first low-impedance conductive trace 2014 away from the connector 50). The printed conductive trace 317 is electrically connected with a terminal of the first low-impedance conductive trace 2012 and a second terminal of the first low-impedance conductive trace 2013 (i.e., the terminal of the first low-impedance conductive trace 2013 away from the connector 50). Due to the arrangement of the printed conductive traces 316 and 317, the first low-impedance conductive traces 2011, 2012 can be electrically connected with another set of first low-impedance conductive traces 2013, 2014, which are connected with the connector 50. Preferably but not exclusively, the connector 50 is a sold pad, a via hole, a connecting copper foil or a connecting terminal.

From the above descriptions, the present invention provides a circuit board with a hybrid wiring structure. The use of the low-impedance wiring set can provide good conductivity and satisfied conductive stability. Due to the printing characteristics of the printed wiring sets, the overall wiring flexibility can be further improved. Consequently, the circuit board can be suitably applied to various electronic components. For example, the electronic components include illumination modules or light-emitting units with different light-emitting surfaces, resistors, capacitors, inductors, transistors, integrated circuits, optocouplers, connectors or relays. In addition, the circuit board with the hybrid wiring structure can be used as a bridge circuit between low-impedance wiring sets. In addition, the manufacturing process is simple, and the generation of chemical pollutants can be effectively reduced. In other words, the technologies of the present invention are industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A circuit board with a hybrid wiring structure, the circuit board comprising:
a substrate having a first surface and a second surface, which are opposed to each other;
at least one low-impedance wiring set having a first resistance value, and comprising at least one first low-impedance conductive trace, wherein the at least one first low-impedance conductive trace is formed on the first surface of the substrate; and
at least one printed wiring set having a second resistance value, and comprising at least one printed conductive trace, wherein the at least one printed conductive trace is formed on the first surface of the substrate, and the at least one printed conductive trace is electrically connected with the at least one first low-impedance conductive trace, wherein the second resistance value is higher than the first resistance value.

2. The circuit board according to claim 1, wherein the at least one printed wiring set is formed by printing conductive ink on the first surface of the substrate, wherein the conductive ink is made of silver paste, copper paste, copper-silver mixed paste or carbon material.

3. The circuit board according to claim 1, wherein the circuit board further comprises a connector, and at least one first low-impedance conductive trace include a plurality of first low-impedance conductive traces, wherein two terminals of the connector are electrically connected with two of the plurality of first low-impedance conductive traces, respectively.

4. The circuit board according to claim 3, wherein the connector is a sold pad, a via hole, a connecting copper foil or a connecting terminal.

5. The circuit board according to claim 1, wherein the circuit board further comprises at least one illumination module, and the at least one illumination module is installed on the first surface of the substrate, wherein the at least one printed wiring set is electrically connected with the at least one illumination module in series or in parallel.

6. The circuit board according to claim 1, wherein one of the at least one printed conductive trace has a current limiting resistor.

7. The circuit board according to claim 1, wherein the substrate is made of glass fiber epoxy resin, paper phenolic resin, glass fiber composite epoxy resin, ceramic material, polyimide or polyethylene terephthalate.

8. The circuit board according to claim 1, wherein a ratio of a resistivity of the low-impedance wiring set to a resistivity of the printed wiring set is less than or equal to 0.3.

9. The circuit board according to claim 1, wherein the circuit board further comprises at least one electronic component, and the at least one electronic component is installed on the first surface of the substrate, wherein the at least one printed wiring set is electrically connected with the at least one electronic component, and the at least one electronic component comprises a resistor, a capacitor, an inductor, a transistor, an integrated circuit, an optocoupler, a connector or a relay.

10. The circuit board according to claim 1, wherein the circuit board further comprises at least one second low-impedance conductive trace, wherein the at least one second low-impedance conductive trace is formed in the substrate and extended toward the second surface of the substrate, and the at least one second low-impedance conductive trace is electrically connected with the at least one first low-impedance conductive trace.

11. The circuit board according to claim 1, wherein the circuit board further comprises at least one additional conductive trace, wherein the at least one additional conductive trace is formed in the substrate and extended toward the second surface of the substrate, and the at least one additional conductive trace is electrically connected with the at least one first low-impedance conductive trace, wherein the additional conductive trace has a third resistance value, and the third resistance value is higher or lower than the first resistance value.
